(19) United States
(12) Patent Application Publication
(10) Pub. No.: US 2006/0099731 A1
(43) Pub. Date: May 11, 2006

(54) Method of patterning a functional material on to a substrate

(75) Inventors: Alastair Robert Buckley, Edinburgh (GB); Christopher Ian Wilkinson, Midlothian (GB)

Correspondence Address: HOWSON AND HOWSON, SUITE 210, 501 OFFICE CENTER DRIVE, FT WASHINGTON, PA, 19034, US

(73) Assignee: MicroEmissive Displays Limited, Edinburgh (GB)

(21) Appl. No.: 10/531,672

(22) PCT Filed: Oct. 14, 2003
(86) PCT No.: PCT/GB03/04466

§ 371 Date: Sep. 14, 2005

(30) Foreign Application Priority Data
Oct. 16, 2002 (GB) 0224121.4

(51) Int. Cl. H01L 51/40

(52) U.S. Cl. 438/99

(57) ABSTRACT

A method of patterning a functional material (150) onto a substrate (100) comprises the steps of (a) applying a layer of protective material (130), soluble in a solvent in which the functional material is insoluble, to at least one major surface of said substrate; (b) removing areas of said layer (130) to gain access to the substrate in well-defined regions; (c) depositing the functional material (150) at least onto the substrate in the well-defined regions; and (d) removing the remaining layer of protective material from the substrate by dissolution in said solvent.

### BACKGROUND OF THE INVENTION

This invention relates to a method of patterning a functional material on to a substrate. The invention has particular application to electronic devices such as polymer light emitting diode (PLED) devices. However, the invention is also applicable to other electronic devices and to biochemical sensors.

PLED devices have been known for approximately 15 years. In such devices, one or more layers of organic material are sandwiched between two electrodes, an anode and a cathode. An electric field is applied to the device, causing electrons to be injected from the cathode into the device and positive charges, typically referred to as holes, to be injected from the anode contact into the device. The positive and negative charges recombine in the electroluminescent organic layer and produce photons of visible or near infrared light. The energy of the photons generated depends on the chemical structure and the electronic properties of the electroluminescent organic layer in which the photons are generated.

Consequently, the color of the light emitted from a PLED can be controlled by careful selection of the organic electroluminescent material. In addition, color filters or color changing materials may be used to alter the color of the light emitted from the electroluminescent layer of the PLED.

PLED displays are predicted to play an important role in small, portable electronic devices such as pagers, mobile phones or head mounted displays but they are also seen as a feasible alternative for larger displays, for example for laptop computer or television screens. PLEDs are able to generate sufficient light to be used in displays under a variety of ambient light conditions (from little or no ambient light to bright ambient light). PLED devices can be fabricated relatively cheaply. PLEDs have a very low activation voltage that is compatible with standard CMOS (complementary metal-oxide-semiconductor) (3.5 V), a fast response time if the emissive layers are very thin (around 100 nm) and a very high brightness. The brightness of a PLED is in the first instant proportional to the electrical current passing through the device. Furthermore, PLED have the added advantage that their emission is approximately Lambertian, which results in a very wide viewing angle.

A PLED may be designed to be viewed either from the “top” (i.e. light is emitted through the contact that is furthest away from the substrate), which is referred to as “top emitting”, or from the “bottom” (i.e. through the transparent substrate), which is referred to herein as “bottom emitting”. The structure between the viewer and the organic light emitting material should be sufficiently transparent to allow the emitted light to be passed through. In many applications it is advantageous to build “top emitting” PLEDs, for example when the substrate material is non-transparent, and/or when the display is built directly onto opaque silicon driver chips for active matrix addressing.

Displays based on organic electroluminescent materials are usually composed of a two dimensional matrix of pixels, each of which comprises a PLED. Such displays generally include an addressing circuit to control the matrix of pixels. In an active matrix PLED, the row and column structure is build into the substrate using standard semiconductor fabrication techniques. In this case, the substrate has an array of discrete electrodes, each one corresponding to a point in the matrix.

In contrast, in a passive matrix addressed PLED display, numerous PLEDs are formed on a single substrate and arranged in groups forming a regular grid pattern. Several PLED groups forming a column of the grid may share a common anode or cathode line. The individual PLEDs in a given group emit light if their anode line and cathode line are activated at the same time.

A display based on organic electroluminescent materials can be monochromatic, that is, each pixel emits light of the same color. The thin organic electroluminescent film in such monochrome displays is usually formed via a spin-coating process to obtain a uniform polymer film of controlled thickness.

Alternatively, various pixels of a display based on organic electroluminescent materials may emit light in various different colors. A full-color display is formed from an array of pixels comprising at least one red, one green and one blue sub-pixel. The sub-pixels in any particular pixel can be activated in various combinations to generate an entire spectrum of colors.

Although substantial progress has been made in the development of full-color PLED displays, additional challenges remain. One approach to generate full-color PLED displays is to provide a self-emissive pixelated display with adjacent PLED sub-pixels emitting red, green and blue light. This approach would give, in principle, the most efficient display structure, as no light would be lost through absorption by a color filter or a color changing material. However, the main obstacle to overcome here is the compatibility of the solvents for the red, green and blue polymers. Currently used light emitting polymers for display applications are in general soluble in the same limited range of aromatic non-polar solvents which include, but are not limited to, toluene, xylene, chloroform and tetrahydrofuran. As a consequence, after having deposited a first layer of said polymer material from a solution and patterned it using various processes describes below, any subsequent deposition of a second polymer layer from a common solvent will result in either a complete removal of the previously deposited polymer film or a mixing of the two polymers. Both scenarios are not desirable as they lead either to a complete device failure or to color contamination and bad control over color coordinates. Mixing of the polymers can even happen without using a common solvent for the two polymers. Consequently direct contact between light emitting polymers during a deposition process and/or a patterning process should be avoided.

An additional problem related to organic light emitting materials is that they are very delicate and cannot be directly exposed to any processing steps such as plasma etching or UV radiation without suffering severe damage. Process induced damages reduce the device lifetime, decrease the photoluminescence efficiency and quantum efficiency of the device and lead to generally not acceptable device performance.

To overcome the problems described above a variety of technologies and processes have been developed. In the following section, various technologies and processes are discussed in more detail and their limitations for achieving high resolution, efficient and reliable polymer light emitting displays with small feature size are highlighted.

Inkjet-printing is one technology that has emerged, which overcomes solvent compatibility problem and prevents the red, green and blue polymers from mixing during the deposition process. In Inkjet-printing tiny drops of a given polymer solution are dispensed onto a substrate on which already exists a structure of pre-patterned pixels. The volume of the respective polymer solution is controlled very accurately so that each pixel is filled precisely and no spillage or mixing of polymers occurs during this process. Inkjet-technology has found widespread applications in the production of PLED displays and is now considered an efficient manufacturing route for full color PLED displays. However, inkjet technology is currently only applicable to displays with pixel sizes of greater than 30 micrometers. The minimum pixel size that can be achieved with inkjet printing technology is very much proportional to the smallest droplet size that can be dispensed reproducibly. The smallest droplet size that can be dispensed at the time of writing is around 25-30 micrometers. Therefore producing displays with a pitch of 10 micrometers is not possible, as one droplet would automatically cover three pixels. Other problems related to ink-jet printing in such small dimensions are volume control of the droplets, placement accuracy of the polymer droplet and the positioning accuracy of the ink-jet print nozzle.

An alternative approach for making full color PLED displays is to use a white emitting polymer in combination with a color filter that is precisely aligned over each PLED sub pixel. The color filters transmit certain discrete wavelengths generating red, green or blue light for specific sub-pixels. The disadvantage of this approach is that color filters absorb a significant proportion of the initially emitted light and are therefore very inefficient

A more efficient technique is to use a monochrome PLED array in combination with color conversion materials which are aligned accurately to the individual sub pixels. The working principal of color conversion materials is that they absorb higher energy photons (low wavelength light) and emit photons at a lower energy (higher wavelength) by fluorescence or phosphorescence (see U.S. Pat. No. 5,294,870). This approach has the potential disadvantage of color bleeding of blue light into red pixels since the red dyes might not efficiently absorb the blue light. Another problem with this approach is that efficient color conversion materials that can be patterned to 4-5 micrometer size are, to our knowledge, not readily available.

A patterning process for polymer light emitting materials based on a lithography process would certainly be one route to achieve full color polymer displays. In the literature a publication by D. G. Lidzey et al. Synthetic Metals 82 (1996) describes a patterning process for polymer light emitting diodes using a standard photolithography process consisting of the following steps: A thin polymer film is spin-coated onto a substrate, then a layer of photoresist is spin-coated onto the polymer layer. The photoresist is then exposed through a shadow masked, developed and the exposed photoresist is then washed off. The cathode metal is then evaporated making contact to the light-emitting polymer where the exposed photoresist has been washed off. The remaining photoresist is then dissolved in acetone.

The process described by Lidzey et al. describes the patterning of the cathode metal using a photolithography process. This process could be used to define pixels for a monochrome display but it is not suitable for full color display application, as it does not describe a method for avoiding contamination of the light emitting polymers during processing and it does not avoid polymer mixing.

A different approach to pattern the metal cathode was proposed by Kim et al. (Science, Vol. 288, 5 May 2000). This process describes the patterning of the cathode of organic light emitting diodes using a cold welding process. In this process, a metal-coated stamp composed of a rigid material such as Si is pressed onto an unpatterned film consisting of the organic device layers coated with the same contact layer as that used to coat the stamp. When a sufficiently high pressure is applied, an intimate metallic junction is formed between the metal layers on the stamp and the film, leading to a cold-welded bond. When the stamp and the film are separated, the metal cathode breaks sharply, forming a well-defined patterned electrode.

This process is applicable to produce monochrome displays but does not lend itself to the production of full color RGB displays as it is only able to pattern the cathode and not the light emitting material. Another drawback of this process is that it does not work very well with top emitting active matrix displays that require transparent, highly reactive, low work function thin film cathodes from materials like calcium, magnesium etc. These materials do not lend themselves to the cold welding process because they react very aggressively and form oxides or nitrides at the interfaces that prevent an effective cold welding process.

A different way of patterning materials has been developed in recent years using laser ablation. This technique uses excimer laser radiation in the wavelength range from 192 mm to 332 nm to selectively ablate material of a substrate. There have been various publications about possible applications of this technique and the most relevant to our invention will be discussed here in more detail.

Noach et al. (Appl. Phys. Lett. 69 (24), 1996) reported on the microfabrication of light emitting diode arrays made from light emitting conjugated polymers. The process is based on the direct photoablation with the 193 nm emission of an excimer laser. The process described in this paper comprises of the following steps: 1) patterning of the indium tin oxide (ITO) covered glass substrate using the excimer laser, 2) spin-coating the light emitting polymer onto the patterned substrate, 3) evaporation of the cathode contact (aluminum), 4) ablation of both aluminum and partially the polymer layer via excimer laser radiation through a bar grid that was placed orthogonally relative to the direction of the original ITO lines. This process again allows the fabrication of monochrome displays but it does not allow the production of full color displays as the deposition of a second polymer via spin coating would dissolve or damage the already patterned pixels.

Another process to obtain full color displays via excimer laser patterning has been described in WO 99/03157. This process basically comprises the following steps:
I. Deposition of first organic light emitting material(s) onto a substrate that is overlaid with a preferably transparent hole-transporting layer.
II. Deposition of an electron injection material (MgAg) on to said first organic layer.
III. Selective laser ablation of both the electron injection material and the first organic light emitting material from undesired areas of the substrate to obtain pixels that emit a first color of light.
IV. Deposition of second light emitting material(s) on to said substrate.
V. Deposition of an electron injection material (MgAg) on to said second organic layer.
VI. Selective laser ablation of both the electron injection material and the first organic light emitting material from undesired areas of the substrate to retain the pixels that emit a first color of light and to create pixels that emit a second color of light
VII. The same process steps as described above are repeated to obtain pixels that emit a third color of light

The above process is certainly feasible if the organic materials are evaporated or deposited from solid state. However, for solution processed organic light emitting materials such as most conjugated polymers e.g. poly(phenylene vinylene) (PPV), polyfluorenes, etc this process will not work Most conjugated polymers that are currently used in the field of organic light-emitting displays are soluble in non-polar aromatic solvents. This means that process step 1V in the above process would wash off or contaminate the first organic layer that has been deposited. This would lead to ill-defined device characteristics and very likely to a complete device failure.

Another application of patterning materials using excimer radiation is described in EP-A2-0480703. In this document, a process is described to pattern metal onto a substrate. For this purpose, one or more metal films are deposited onto the same substrate, at least one of them being highly UV-absorbing. The resulting structure is scanned with a UV laser having sufficient power to ablate the first and, if applicable, second layer from the substrate in a pattern that is determined by the scanning pattern of the laser beam. It is reported that if the substrate is a polymer the portion of the substrate from which the metal was ablated is greatly roughened.

Such damage is not acceptable to any electro-optically active material as employed in the field of organic light emitting diodes and polymer electronics. Any damage will alter the properties of the organic materials in an ill-defined manner and will have undesired consequences on both lifetime and performance. Similar problems were also reported in WO 98/53510. In this document, the cathode was pre-patterned using laser ablation but then a second method that was less destructive than laser ablation to the underlying organic layers was necessary to complete the patterning.

A very general approach to transferring a pattern onto a substrate is described in U.S. Pat. No. 5,505,320. A first layer of a first material is deposited onto a substrate followed by a second layer of material where the second layer is of different material from the first layer. A layer of a dry imaging polymeric composition is then deposited on top of the second layer and an excimer laser is used to define a pattern in the dry imaging polymeric composition. The exposed portions of the second layer are then etched with the first layer acting as an etch stop. The remaining dry imaging polymeric material is ablated from the defined area to expose the second layer of material. After this, the remaining exposed areas of the first layer are etched to expose the substrate.

The above-mentioned document describes how a certain pattern can be transferred into metal layers that have been deposited onto a substrate to obtain interconnection between electronic circuits. However, this process cannot be used for a pattering process of organic electro-optically active material like light emitting diodes. There is no mention in the document of how to overcome the compatibility problem of the solvents for the red, green and blue emitting material, or in other words how can it be assured that the previously deposited light emitting polymer is not washed off if the second polymer is deposited from solution? It is also not clear from this document how to remove material one and material two after the organic light-emitting polymer has been deposited.

A very similar process to that outlined above is described in patent U.S. Pat. No. 5,196,376. In this patent, a thin layer of polymer is deposited onto a metal layer by vaporizing a corresponding monomer in a vacuum and allowing the same to deposit onto the layer of metal substantially as a polymer. The said polymer layer is then patterned with a laser by removing said polymer to expose selected areas of the metal layer therebeneath, selectively etching the exposed areas of the metal to pattern a metal layer in accordance with a pattern defined by the thin layer of polymer. This process is also not applicable to patterning organic light emitting polymers, as it gives no clue as to how to overcome the compatibility problems of the solvent in which the light emitting polymers are dissolved. It is also not apparent from this patent how the polymer layer that has been used to define the pattern and the metal layer can be removed without damaging the light emitting polymers. The suggested process of plasma etching will lead to unrecoverable damage of the light-emitting polymer.

The discussion above emphasizes an existing problem in the production of full color display. One can either apply a uniform single coating of a light emitting polymer from a solution via spin coating and pattern it using various techniques to achieve high resolution monochrome devices and then convert the light via color filters or color changing materials but with the consequent light loss; or selectively deposit individual polymer color elements via e.g. inkjet printing but then have a more expensive and less scalable process for volume production that does not lend itself to pixel sizes below 30 μm.

### SUMMARY OF THE INVENTION

According to the invention there are provided a method of patterning a functional material on to a substrate according to claim 1, a device according to claim 28 and an optoelectronic device according to claim 29. Preferred or optional features of the invention are defined in the dependent claims.

The present invention provides a universal patterning process for organic light emitting polymers. It is based on the use of at least one sacrificial, preferably organic, layer that firstly must be soluble in a solvent system which does not cause any non-recoverable damage to the functional, e.g. organic electroluminescent material, secondly protects the underlying functional material from any potentially damaging solvents or process steps and thirdly, is removable using a solvent system that does not attack or cause any non-recoverable damage to the fictional material.

A particular species of the present invention provides a method of patterning and fabricating color PLED displays. Preferably, the present invention relates to methods for fabricating full-color PLED displays that have red, green and blue sub-pixels that can be activated in any combination to produce any color in the visible or near infra red light spectrum. This process can be used to produce self-emissive, pixelated displays with adjacent sub-pixels emitting red, green and blue light. The patterning of each different light emitting material occurs in a process that is detailed herein. A first layer of material, preferably a water-soluble organic material such as poly(vinyl alcohol) (PVA) is deposited on to a substrate. The first layer of material should be soluble in a solvent system that is incompatible with the solvent system of the organic electroluminescent material and it should not cause any significant damage to the functionality of the electroluminescent material. The thickness of the protective organic layer should be less than 1 μm. Then a second layer of material, preferably a thin metal layer with a thickness of less than 150 nm is deposited onto the first layer of material. The thin metal layer ideally consists of aluminum, nickel, chromium, or any other metal that can be easily removed via a laser ablation technique.

We have successfully shown that for example water based polymers such as PVA can be deposited onto and later removed from the organic electroluminescent material without causing any change in the photoluminescent spectra of the organic electroluminescent materials. The performance of electroluminescent devices that were fabricated from polymer films that were exposed to water prior to the cathode deposition was also comparable to that of standard devices, if the adsorbed water had been removed from the polymer film using a thermal process.

In a subsequent step of the preferred method, well defined areas of the second layer of material are ablated to expose certain well defined areas of the first layer of material, in this case PVA. Ablation of the metal can be carried out by exposing said layer to at least one shot/dose of excimer laser radiation with a wavelength of preferably 322 nm. The exposed PVA is subsequently etched to give access to the substrate and to define the pixel. Care has to be taken of not to damage the functionality of the underlying substrate and therefore the choice of a suitable etching solvent for the PVA layer is important. The etching of the organic protective layer is achieved by exposing the substrate to a solvent that removes/dissolves the organic protective layer. The dimension of the pixel openings can be controlled via the etch time and a suitable choice of solvent system. (For example using a 50/50 isopropyl alcohol (IPA)/water solution instead of water to etch PVA reduces the etch rate significantly and gives better process control). The minimum size of the pixel opening is however determined by the thickness of the protective organic layer if we assume an isotropic etch.

The next step is to deposit the electroluminescent organic material onto the substrate e.g. via a spin coating process. This leaves a conformal film of organic electroluminescent material covering the exposed areas of the substrate as well as the upper surface of the metal layer. The minimum pixel size that can be filled will depend on the aspect ratio of the pixel, but given the most suitable parameters, this process will allow the filling of openings as small as 1 μm. There is no upper limit for the size of the pixel that can be filled using this process.

A third layer of material, preferably a water-soluble organic material such as PVA, is nextly preferably deposited onto the substrate via spin coating. This layer covers the electroluminescent organic material in such a way as to protect the underlying electroluminescent material from potentially damaging environments and to minimize the exposure of the organic electroluminescent material to the laser radiation. Potential damage of the electroluminescent material could occur via photo oxidation or photo bleaching of the electroluminescent polymer film inside the pixels. Another advantage of the second PVA layer is that it protects the underlying organic electroluminescent material from any debris that is produced during the subsequent process steps.

The final step in the process is to remove the sacrificial layers from the substrate. This could potentially be done using a lift off process by dissolving the first PVA layer and subsequently lift off all subsequent layers of the substrate leaving simply the substrate with the electroluminescent material on it However, organic electroluminescent materials tend to form thin conformal films covering over the entire area of the substrate including any layers thereon. The solvent (IPA/water solution for example) used to dissolve the PVA and to lift off the metal should not affect the PLED material. Therefore, the thin conformal PLED film on top of the metal layer prevents any efficient lift off, as no solvent is able to penetrate. The solvent is also not able to penetrate into the first layer of PVA via the sidewalls of the pixel openings because the sidewalls are also covered by a thin film of electroluminescent material that does not allow the solvent to penetrate. For the lift off process to work the conformal electroluminescent film and the thin metal layer has to be punctured/removed from large areas of the substrate. This removal process can be achieved by ablating large portions of the remaining thin metal layer. The ablation process of the thin metal also removes the not required organic electroluminescent layer. After this process all the sacrificial water-soluble material layers can be dissolved This leaves an array of pixels of electroluminescent material on the substrate. Alternatively, puncturing the metal layer can be achieved by using a master wafer that has spikes patterned on it using a standard photolithography process. The dimensions of the spikes are determined by the size of the pixel that is required and the thickness of the first sacrificial organic layer (spike height should be more than the thickness of the metal layer and less than the thickness of metal layer+first sacrificial organic layer) The master wafer is then aligned to the substrate and the two are brought together in a mask aligner for example. The spikes of the master substrate will puncture the metal layer of the on the substrate leaving either holes in the metal layer to etch the pixel openings or puncturing both the PLED film and the metal film to allow a solvent to enter the structure to enable a lift off process. This process is very scalable.

Repeating the process outlined above and changing the emission properties of the organic electroluminescent material used in solution in each repetition, very high resolution, full-color displays with very small pixel size can be produced. In principal, the same process can be applied to produce displays with a variety of pixel sizes on a variety of substrates.

The methods of the present invention are simple and economical. Furthermore, the methods can be used to fabricate color PLED displays using a wide variety of standard materials and standard process equipment.

In a particularly preferred embodiment, the present invention can be used to fabricate high resolution, full-color PLED display having pixels comprising red, green and blue sub-pixels. More preferably, the devices have very small pixel sizes and high brightness and may be “top” emitting or “bottom” emitting displays.

The methods of the present invention allow for patterning of the electroluminescent organic material to fabricate full-color displays that consist of self-emissive pixels. Each pixel contains a number of sub-pixels with each adjacent sub-pixel emitting light of a different color, e.g. red, green and blue light for a full-color display.

In a particular embodiment, the present invention relates to a method of defining pixels within a sacrificial organic layer that has been deposited onto a substrate. The substrate has previously been coated with an organic layer that firstly, facilitates charge injection from the bottom electrode into the device and secondly is largely insoluble in the solvent used to dissolve the electroluminescent organic material and the sacrificial organic material. The organic layer, preferably including polyethylenedioxythiophene (Pedot) and also possibly including one or more further substances such as epoxysilane, has been rendered insoluble by a heat treatment at 120° C. for 15 minutes. The method for defining pixels comprises: 1) Deposition of a sacrificial organic layer onto a pre-treated substrate, with the sacrificial organic material having to fulfill at least the requirements that firstly, the sacrificial organic material is largely insoluble in the solvent used to dissolve the organic electroluminescent material and secondly, the solvent used to dissolve the sacrificial organic material does not damage or dissolve the organic electroluminescent material. 2) The deposition of a thin metallic layer (less than 200 nm) on top of the sacrificial organic layer and subsequent patterning of that thin metal layer by ablating the metal at the desired positions using for example an excimer laser. 3) Removing the sacrificial organic layer from beneath where the metal layer has been ablated via a wet etch process in a solvent that dissolves the sacrificial organic layer to define the pixel openings and access to the said organic layer that facilitates charge injection. 4) Deposition of the organic electroluminescent material onto the substrate where exposed in the pixel openings. 5) Deposition of a second sacrificial organic layer onto the substrate with the second sacrificial organic material having to fulfill at least the requirement that the solvent used to dissolve the sacrificial organic material does not damage or dissolve the organic electroluminescent material. 6) Ablating the remaining metal layer using for example an excimer laser. 7) Dissolving the sacrificial organic layers in a solvent that does not damage the electroluminescent material leaving a substrate with patterned thin films of one type of electroluminescent material on it.

In a preferred version of this embodiment, the method comprises the following further steps: 8) Deposition of a sacrificial organic layer onto the substrate, with the sacrificial organic material having to fulfill at least the requirements that firstly, the sacrificial organic material is largely insoluble in the solvent used to dissolve the organic electroluminescent materials and secondly, the solvent used to dissolve the sacrificial organic material does not damage or dissolve the organic electroluminescent materials. 9) Deposition of a thin metallic layer (less than 200 nm) on top of the sacrificial organic layer and subsequent patterning of that thin metal layer by ablating the metal at the desired positions using for example an excimer laser. 10) Removing the sacrificial organic layer from beneath where the metal layer has been ablated via an etch process to define the pixels and open up access to the said organic layer that facilitates charge injection. 11) Deposition of a second type of organic electroluminescent material onto the substrate and into the pixels. 12) Deposition of a further sacrificial organic layer onto the substrate with the further sacrificial organic material having to fulfill at least the requirements that the solvent used to dissolve the sacrificial organic material does not damage or dissolve the organic electroluminescent materials. 13) Ablating the remaining metal layer using for example an excimer laser. 14) Dissolving the sacrificial organic layers in a solvent that does not damage the electroluminescent materials leaving a substrate with patterned thin films of two types of electroluminescent material on it It will be seen that steps (8) to (14) above are a repetition of steps (1) to (7) for the second electroluminescent material. Preferably, these step are again repeated to form sub-pixels of a third organic electroluminescent material, leaving a substrate with patterned thin films of three types of electroluminescent material (red, green and blue) on it.

The method may further comprises the steps of deposition of a top electrode onto the substrate, and/or deposition of a primary encapsulation layer and possibly further encapsulation using a secondary encapsulation.

### BRIEF DESCRIPTION OF THE DRAWINGS

The invention will now be described in more detail, by way of example only, with reference to the accompanying drawings, in which:

FIGS. 1 to 11 are schematic sectional views showing sequential steps in the fabrication of an optoelectronic device according to the method of the invention; and

FIGS. 12 to 19 are schematic sectional views showing sequential steps in the fabrication of an optoelectronic device according to an alternative method

### DETAILED DESCRIPTION OF INVENTION

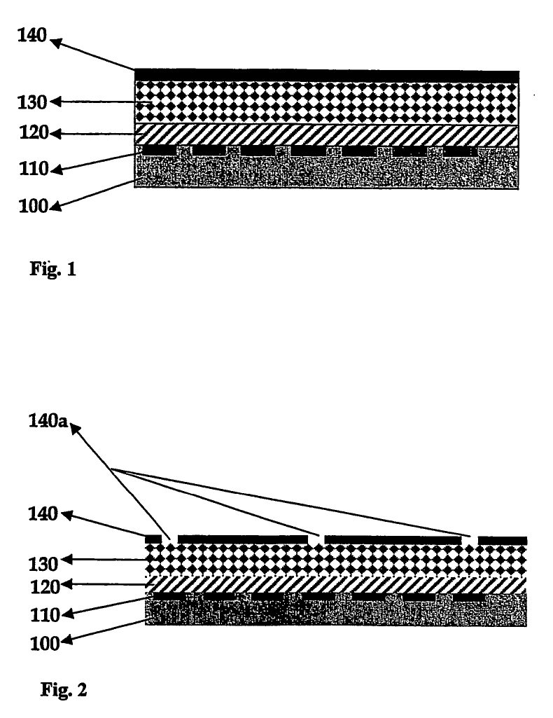

FIG. 1 shows a device comprising a substrate 100, which can be transparent or opaque, a patterned bottom electrode 110, which can be a cathode or an anode and an organic layer 120 that firstly facilitates charge injection from the bottom electrode into the device and secondly is largely insoluble in the solvent used to dissolve the electroluminescent organic material and the sacrificial organic material described below. The layer 120 is a charge injection layer, i.e. a hole transporting layer e.g. Pedot-PSS (polyethylenedioxythiophene-polystyrene sulphonate) if the bottom electrode 110 is an anode, and an electron transport layer if the bottom electrode is a cathode. A sacrificial organic layer 130 e.g. of poly(vinyl alcohol) is insoluble in the solvent used to dissolve the organic electroluminescent material described below. The solvent system used to spin coat the sacrificial organic layer 130 should not cause any damage to the charge injection layer or damage/dissolve the organic electroluminescent material. A thin metal layer 140 of a thickness of less than 200 nm, e.g. of aluminum, overlies the sacrificial organic layer 130. Each element of the bottom electrode represents one sub-pixel in the matrix. The electrodes 110 can be patterned by any method known in the art, including, but not limited to lithographic, particularly photolithographic techniques, laser ablation, and masking during deposition.

In FIG. 2, the thin metallic layer 140 has been directly patterned via laser ablation process removing the metallic layer and giving access to the sacrificial organic layer 130 at specific positions 140a.

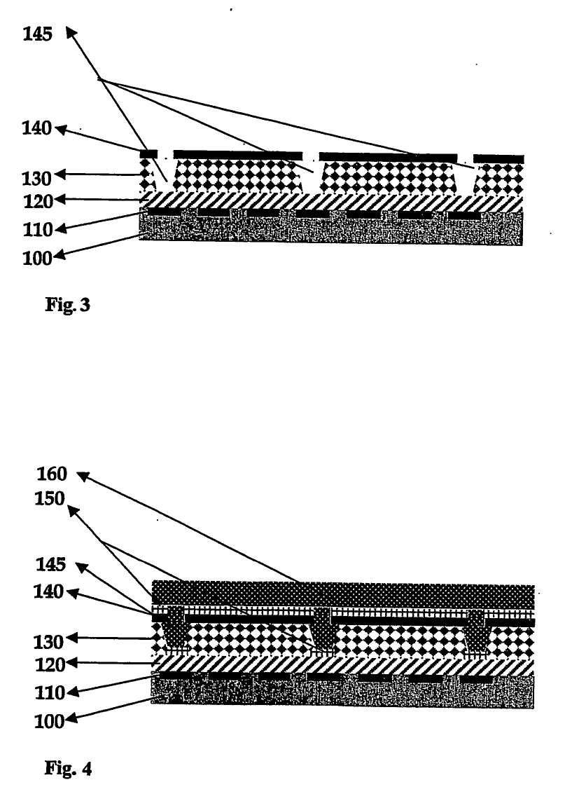

The sacrificial organic layer 130 is then removed from beneath the position 140a using a wet etch process e.g. in a water/IPA (isopropyl alcohol) solution to define the pixels 145 with the first organic layer 120 acting as an etch stop. This process is indicated in FIG. 3. The organic layer 120 acts like an etch stop as it is insoluble in the solvent system used to etch pixel openings in the sacrificial organic layer 130.

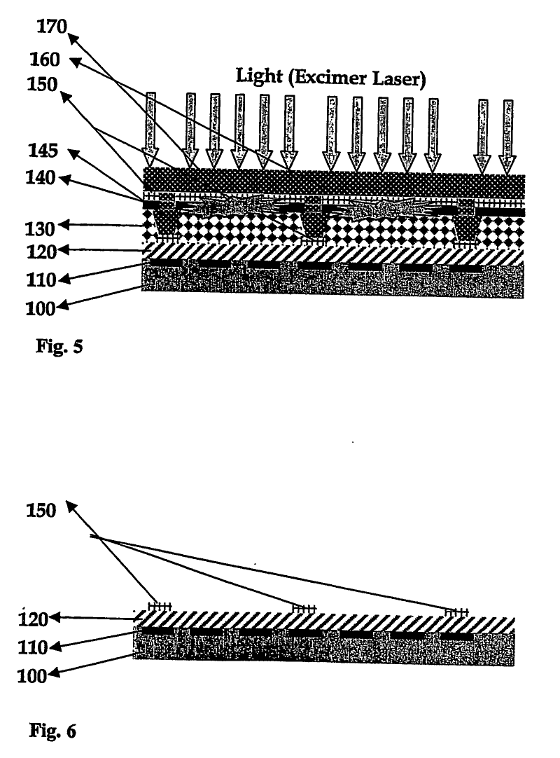

In the next step electroluminescent material, e.g. for providing sub-pixels emitting light of a first primary color, is deposited onto the wafer, filling in the pixels 145 and forming a conformal thin film 150 over the entire structure. An additional sacrificial organic layer 160, preferably of the same material as the first sacrificial organic layer 130, is deposited onto layer 150, filling in the pixels 145 and covering the entire structure as indicated in FIG. 4. The remaining metal layer 140 is then ablated or punctured as indicated by 170 using light with a suitable energy from, for example, an excimer laser source. The metal layer can either be ablated using a flood exposure of the entire substrate or, by using suitable optics the light can be guided through a suitable mask in such a way that the pixels 145 are not exposed to any light This process is shown in FIG. 5.

The remaining sacrificial organic layers 130 and 160 are then dissolved in a suitable solvent. The solvent is able to penetrate into the organic layer 130 via the ablated area 170. After the sacrificial organic layers 130 and 160 have been removed, the substrate is left with electroluminescent material 150 on top of the charge injection layer 120 at the position 145 as shown in FIG. 6.

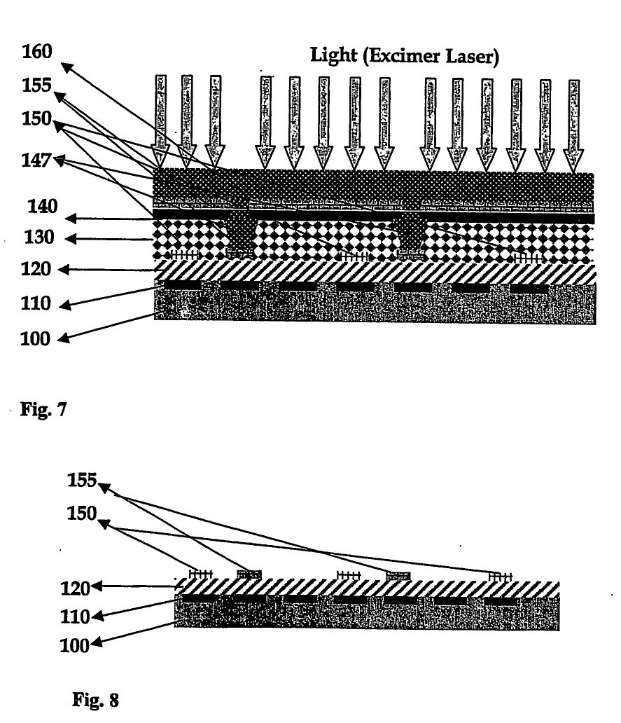

As shown in FIG. 7, a second electroluminescent material, e.g. providing sub-pixels of a second primary color, can then be patterned onto the same substrate 100 in a very similar way as described and detailed in FIGS. 1-6. A sacrificial organic layer 130 is deposited onto the substrate 100 covering the entire substrate 100 including the electroluminescent material 150. A metal layer 140 is then deposited onto the sacrificial layer 130. The metal layer is then patterned and the metal layer is partially removed via an ablation or stamping technique so that a pixel 147 can be defined that is adjacent to the location of the thin film of the first electroluminescent material 150. The sacrificial organic layer 130 is then etched defining the pixels 147. A second type of organic electroluminescent material 155 is then deposited. After that a second sacrificial organic layer 160 is deposited onto layer 155 and the remaining metal is either ablated via exposure of the substrate to a suitable light source (excimer laser) or punctured.

The remaining sacrificial organic layers 130 and 160 are then dissolved in a suitable solvent The solvent is able to penetrate into the organic layer 130 via the ablated area. After the sacrificial organic layers 130 and 160 have been removed, the substrate is left with electroluminescent material 150 and 155 on top of the charge injection layer 120 as shown in FIG. 8.

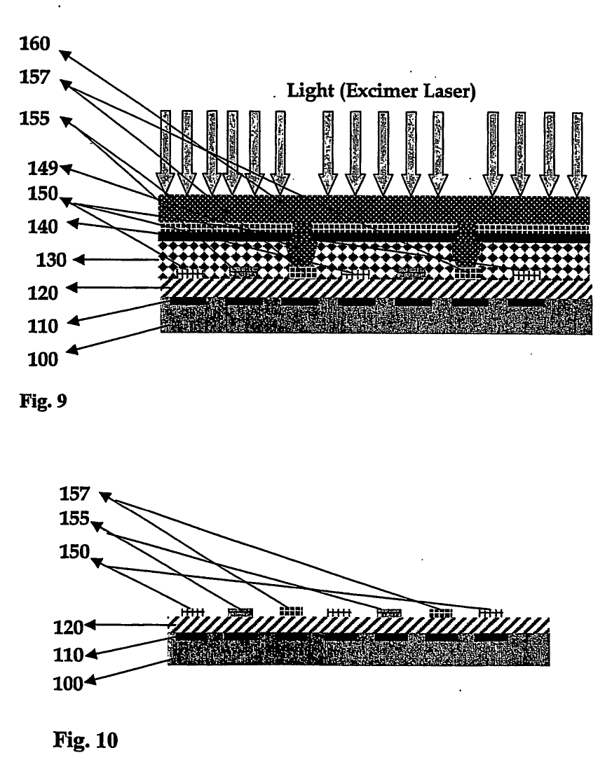

As shown in FIG. 9, a third electroluminescent material, e.g. providing a third primary color, can be patterned onto the same substrate 100 in a very similar way as described and detailed in FIGS. 1-6. A sacrificial organic layer 130 is deposited onto the substrate 100 covering the entire substrate 100 including the electroluminescent material 150 and 155. A metal layer 140 is then deposited onto the sacrificial layer 130. The metal layer is then patterned and the metal layer is partially removed via an ablation technique so that a pixel 149 can be defined that is adjacent to the location of the thin film of electroluminescent material 150 or 155. The sacrificial organic layer 130 is then etched defining the pixels 149. A third organic electroluminescent material 157 is then deposited. After that a second sacrificial organic layer 160 is deposited onto layer 157 and the remaining metal is ablated or punctured via exposure of the substrate to a suitable light source (excimer laser).

The remaining sacrificial organic layers 130 and 160 are then dissolved in a suitable solvent. The solvent is able to penetrate into the organic layer 130 via the ablated area. After the sacrificial organic layers 130 and 160 have been removed, the substrate is left with electroluminescent material 150 and 155 and 157 on top of the charge injection layer 120 as shown in FIG. 10.

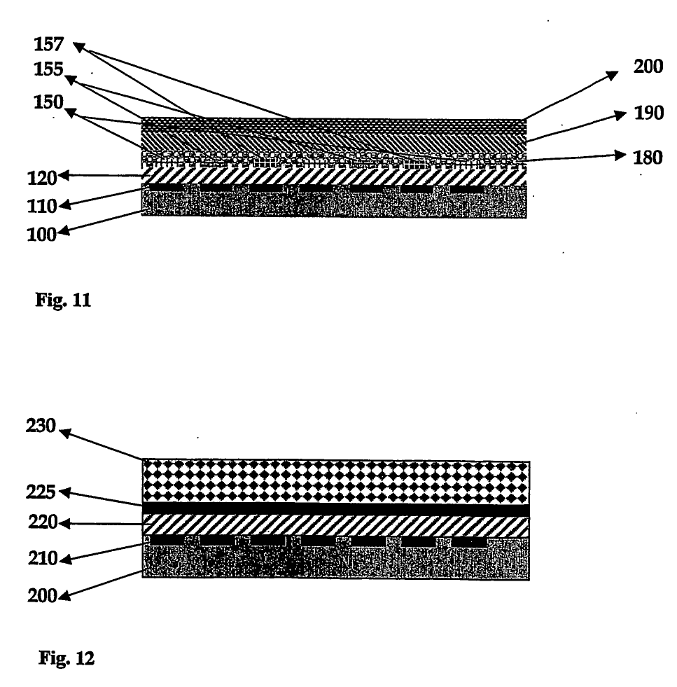

FIG. 11 shows a full color PLED display that has been fabricated by the subsequent execution of the above workflow. The display comprises of a substrate 100, a patterned bottom electrode 110, an organic charge injection layer 120, emitting sub-pixels 150, emitting sub-pixels 155 and emitting sub-pixels 157, a semi-transparent top electrode 180, a primary thin film encapsulation 190 and a secondary encapsulation 200.

PLEDs can be fabricated by any method known in the art. The layers of organic material may be formed by evaporation, spin casting, self-assembly or any other appropriate film forming techniques. The thickness of the organic layers can vary between a few monolayers to about 500 nm. In a preferred embodiment, the organic layers are formed by a spin-casting process.

The PLED shown in FIG. 11 is by way of example, and any type can be used. For example, a PLED may comprise a hole injection layer adjacent to the anode and at least a second hole-transporting layer adjacent to the hole-injecting layer. The hole injection layer and the hole transport layer may be deposited separately.

A PLED may comprise an electron injection layer and at least one electron transport layer, or the PLED can further comprise an additional layer adjacent to the top electrode. Other PLED structures will be evident to those skilled in the art.

A substrate may be made from any material known in the art, including glass, silicon, plastic, quartz and sapphire. If the PLED display is formed on a silicon chip, the chip preferably includes drive electronics and one of the sub-pixel electrodes. The top electrode may be common to all sub-pixels.

An anode can have one layer comprising a metal having a high work function, a metal oxide and mixtures thereof. Preferably, the anode comprises a material selected from the group of high work function metal such as gold, platinum, nickel, chromium, or alternatively from the group of conducting or semi-conducting metal oxides or mixed metal oxides such as indium zinc tin oxide, indium zinc oxide, ruthenium dioxide, molybdenum oxide, nickel oxide or indium tin oxide. In one embodiment, the anode further comprises of a thin layer (0.1 to 2 nm) of dielectric material between the anode and the first hole injection/hole transport layer.

Examples of such dielectric materials include, but are not limited to lithium fluoride, cesium fluoride, silicon oxide and silicon dioxide. In another embodiment, the anode comprises a thin layer of an organic conducting material adjacent to the hole injection/hole transport layer. Such organic conducting materials include, but are not limited to, polyaniline, Pedot-PSS, and a conducting or semiconducting salt thereof.

A semi-transparent cathode, such as used in FIG. 11 comprises a single layer of one or more metals or metal oxides, at least one of them having a low work function. Such metals include, but are not limited to, lithium, aluminum, magnesium, calcium, samarium, cesium and mixtures thereof. In one embodiment, the cathode further comprises a layer of dielectric material adjacent to the electron injection/electron transporting layer, the dielectric material including, but not limited to, lithium fluoride, cesium fluoride, lithium chloride and cesium chloride.

In an second embodiment the patterning process is slightly different. FIG. 12 shows a device comprising a substrate 200, which can be transparent or opaque, a patterned bottom electrode 210, which can be a cathode or an anode and a first organic layer 220 that firstly facilitates charge injection from the bottom electrode into the device and secondly is largely insoluble in the solvent used to dissolve the electroluminescent organic material and the sacrificial organic material described below. The layer 220 is a charge injection layer, i.e. a hole transporting layer e.g. Pedot-PSS (polyethylenedioxythiophene-polystyrene sulphonate) if the bottom electrode 210 is an anode, and an electron transport layer if the bottom electrode is a cathode. A second organic layer 225 comprises a functional material e.g. organic electroluminescent material. The solvent used to dissolve the functional material 225 must not dissolve the layer 220. A sacrificial organic layer 230 e.g. of poly(vinyl alcohol) is insoluble in the solvent used to dissolve the organic electroluminescent material described above. The solvent system used to spin coat the sacrificial organic layer 230 should not cause any damage or dissolve the organic electroluminescent material.

Each element of the bottom electrode represents one sub-pixel in the matrix. The electrodes 210 can be patterned by any method known in the art, including, but not limited to lithographic, particularly photolithographic techniques, laser ablation, and masking during deposition.

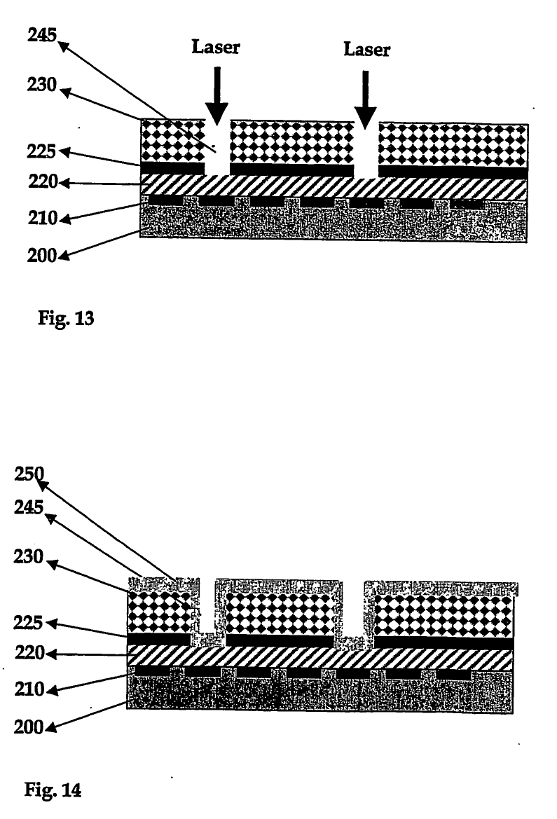

As depicted in FIG. 13, well defined areas of the sacrificial organic layer 230 and of the layer of functional material 225 are removed via a laser ablation process to define spaces for pixels 245 of a second functional material, with the first organic layer 220 acting as an ablation stop.

In the next step the second functional material e.g. for providing sub-pixels emitting light of a second primary color, is deposited onto the wafer, filling in the pixels 245 and forms a conformal thin film 250 over the entire structure as indicated in FIG. 14.

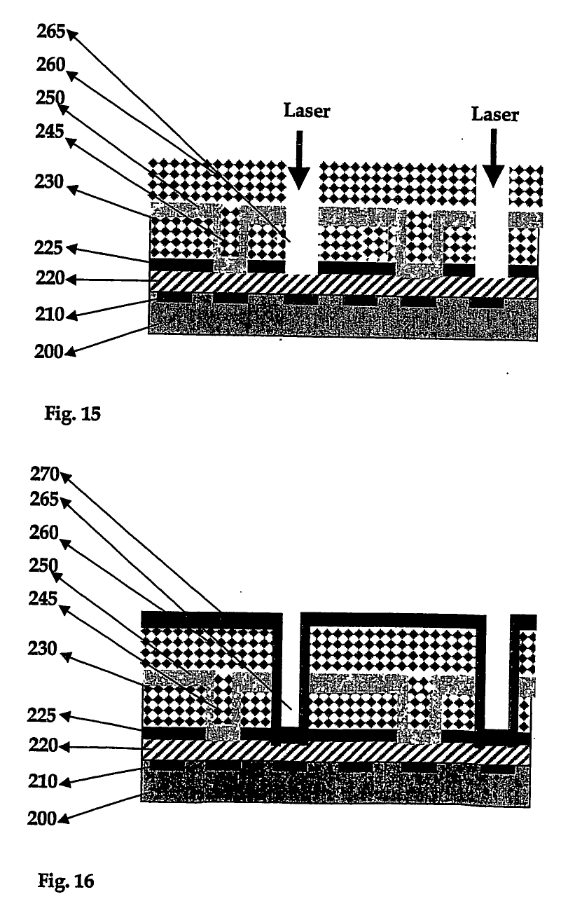

A second sacrificial organic layer 260, shown in FIG. 15, preferably of the same material as the first sacrificial organic layer 230, is deposited onto layer 250, filling in the pixels 245 and covering the entire structure

As depicted in FIG. 15, well defined areas of the sacrificial organic layers 260 and 230 and of the layers of functional material 225 and 250 are removed via a laser ablation process to define the pixels 265 with the first organic layer 220 acting as an ablation stop.

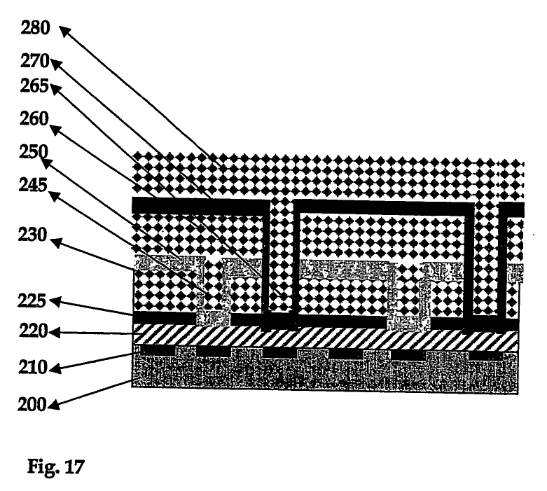

In the next step, a third functional material e.g. for providing sub-pixels emitting light of a third primary color, is deposited onto the wafer, filling in the pixels 265 and forming a conformal thin film 270 over the entire structure as indicated in FIG. 16. FIG. 17 shows a third sacrificial organic layer 280, preferably of the same material as the first and second sacrificial organic layer 230, deposited on to layer 270, filling in the pixels 265 and covering the entire structure.

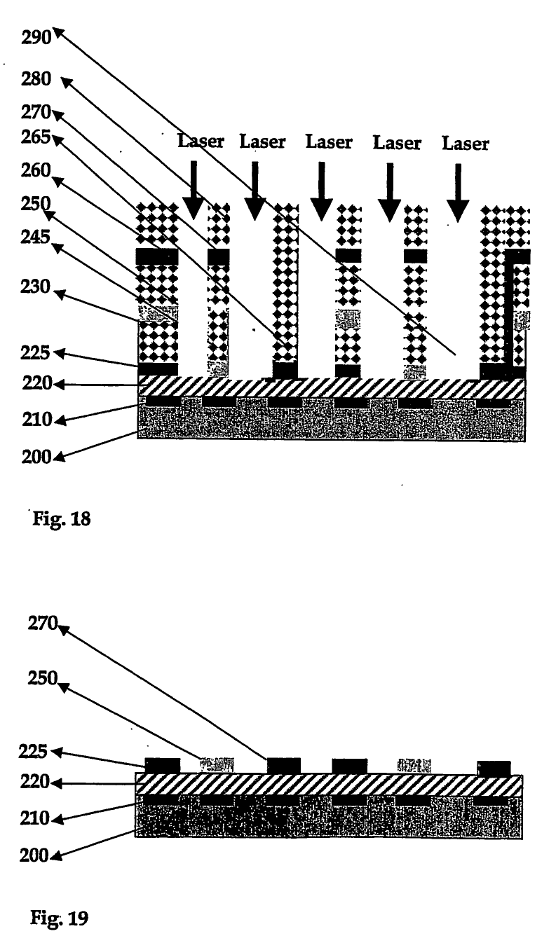

Well defined areas of material 290 are subsequently ablated with the organic layer 220 acting as an ablation stop, as shown in FIG. 18. A suitable solvent that dissolves the sacrificial organic layers 280, 260 and 230 is able to penetrate into said organic layers via the ablated areas 290. After the sacrificial organic layers 230, 260 and 280 have been dissolved, the substrate is left with electroluminescent material 225, 250 and 270 on top of the charge injection layer 220 as shown in FIG. 19.

Whilst the specific embodiments of the invention described above are methods of fabricating an optoelectronic display, the invention has application in a number of different fields such as other electronics applications and also in fabricating biomedical devices in which a number of different biochemical reagents, such as proteins, are to be patterned on to a substrate.

All forms of the verb “to comprise” used in this specification have the meaning “to consist of or include”.

1. A method of patterning a functional group onto a substrate, comprising the steps of: (a) applying a layer of protective material, soluble in a solvent in which the functional material is insoluble, to at least one major surface of said substrate; (b) removing areas of said layer to gain access to the substrate in well-defined regions; (c) depositing the functional material at least onto the substrate in the well-defined regions; and (d) removing the remaining layer of protective material from the substrate by dissolution in said solvent.

2. A method of claim 1, wherein said substrate comprises glass.

3. A method of claim 1, wherein said substrate comprises silicon.

4. A method of claim 1, wherein said substrate comprises plastics material.

5-28. (canceled)

29. A device comprising a substrate bearing patterned electroluminescent material, the substrate and the electroluminescent material being covered by first and/or second layers of protective material, said layers having apertures giving access to well-defined regions of the substrate.

30. An optoelectronic device comprising a substrate and a plurality of sub-pixels comprising polymer light emitting diodes arranged to emit light of different colors, the spacing between said sub-pixels being less than 15 μm.

31. An optoelectronic device according to claim 30, wherein said spacing is less than 10 μm.

32. An optoelectronic device according to claim 31, wherein said spacing is less than 5 μm.

33. (canceled)

34. A method according to claim 1, wherein said substrate comprises a charge injection layer.

35. A method according to claim 1, wherein said protective material comprises organic material.

36. A method according to claim 35, wherein said layer of protective material comprises a water soluble polymer selected from poly(vinyl alcohol), polymethyl ether, polymethylacrylamide, doped polythiophene, polyethylene glycol, and doped polyaniline.

37. A method according to claim 35, wherein said layer of protective material comprises an alcohol soluble polymer.

38. A method according to claim 1, wherein said protective material comprises inorganic material.

39. A method according to claim 38, wherein said protective material is selected from silicon, silicon nitride, and silicon oxide.

40. A method according to claim 1, wherein a layer of a second protective material is applied subsequent to step (a), is removed in the well-defined regions in step (b), and is subsequently removed other than in the well-defined regions.

41. A method according to claim 40, wherein said layer of second protective material comprises an inorganic material.

42. A method according to claim 41, wherein said layer of second protective material is selected from silicon, silicon nitride, and silicon oxide.

43. A method according to claim 40, wherein said layer of second protective material comprises a metal layer.

44. A method according to claim 43, wherein said layer of second protective material is selected from nickel, aluminum, and chromium.

45. A method according to claim 40, wherein, in step (b), said layer of second protective material is removed from the well-defined regions using a first process to expose said areas of said protective material, and wherein said areas of protective material are removed using a second process to gain access to the substrate.

46. A method according to claim 45, wherein said first process comprises laser ablation.

47. A method according to claim 45, wherein said first process comprises a stamping or puncturing process.

48. A method according to claim 45, wherein said first process comprises a photolithography step to define and expose said layer of second protective material in the well-defined regions, and said second process comprises an etching step.

49. A method according to claim 1, wherein, in step (b), said protective material is removed from the well-defined regions by laser ablation.

50. A method according to claim 1, wherein, in step (b), said protective material is removed from the well-defined regions using a lift off process.

51. A method according to claim 1, wherein, in step (c), the functional material is deposited by a method selected from spin coating, evaporation, and sputtering.

52. A method according to claim 1, wherein, in step (c), an additional layer of protective material is applied over the functional material, said additional layer being removed in step (d).

53. A method according to claim 52, wherein said additional layer comprises the same protective material, soluble in a solvent in which the functional material is insoluble.

54. A method according to claim 1, wherein said functional material comprises an organic electro-optically active material.

55. A method according to claim 1, wherein said functional material comprises a biochemical or biological reagent.

56. A method according to claim 1, further comprising the steps of patterning a further functional material to the substrate, the further steps comprising repeating steps (a) to (d) for the further functional material.

57. A method according to claim 1, further comprising the steps, after step (c), of applying an additional layer of protective material; removing areas of said additional layer to gain access to the substrate in additional well-defined regions; and depositing an additional functional material at least onto the substrate in the additional well-defined regions.

58. An optoelectronic device according to claim 30, comprising a quarter video graphic array (QVGA) device.
